(19) United States
(12) Patent Application Publication
(10) Pub. No.: US 2026/0101524 A1
(43) Pub. Date: Apr. 9, 2026

(54) INDUCTIVE DEVICE WITH INTEGRATED INDUCTORS

(71) Applicant: QUALCOMM Incorporated, San Diego, CA (US)

(72) Inventors: Je-Hsiung LAN, San Diego, CA (US); Jonghae KIM, San Diego, CA (US); Ranadeep DUTTA, Del Mar, CA (US)

(21) Appl. No.: 18/908,077

(22) Filed: Oct. 7, 2024

(51) Int. Cl. H01F 27/24; H01F 27/28; H01L 23/00; H01L 23/498; H01L 25/16

(52) U.S. Cl. CPC H10D 1/20; H01F 27/24; H01F 27/28; H10W 70/65; H10W 90/00; H10W 90/728

(57) ABSTRACT

An apparatus includes a substrate that includes a first integrated inductor. The first integrated inductor includes a first core material disposed within a first cavity of the substrate. The first integrated inductor also includes a first set of conductive windings that at least partially encircle the first core material within the first cavity.

### FIELD

Various features relate to integrated circuit devices.

### DESCRIPTION OF RELATED ART

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

State-of-the-art mobile application devices demand a small form factor, low cost, a tight power budget, and high electrical performance. In order to support some functionality, mobile devices can include inductors as part of other components, such as filters, voltage regulators, and the like. As a particular example, a mobile device may include a power management integrated circuit (PMIC) that requires a multi-phase buck regulator with low phase delta for the corresponding signal in each individual voltage regulator. The PMIC manages power provided to various processors or other integrated circuit (IC) devices, which may include scaling voltages up or down using the multi-phase buck regulator or other voltage regulators. Typically, voltage regulators such as multi-phase buck regulators include discrete surface mount device (SMD) inductors that are attached to a substrate or printed circuit board (PCB). These discrete SMD inductors can have high assembly costs due to the internal components and often have large component variation, sometimes as much as 20% variation between two inductors from the same assembly process. This high component variation can result in some inductors having a signal phase delta that is too large to meet operational criteria of the PMIC. Although bin-sorting can be performed to select a subset of inductors from a larger assembly group that have a signal phase delta that is within a range that satisfies operational criteria of the PMIC, the bin-sorting process is time consuming and expensive, and many SMD inductors assembly processes typically result in a low yield for use in advanced PMICs.

### SUMMARY

Various features relate to integrated circuit devices.

One example provides an apparatus that includes a substrate that includes a first integrated inductor. The first integrated inductor includes a first core material disposed within a first cavity of the substrate. The first integrated inductor also includes a first set of conductive windings that at least partially encircle the first core material within the first cavity.

Another example provides a method of semiconductor device fabrication that includes forming a first integrated inductor within a substrate. Forming the first integrator includes forming a first cavity within the substrate. Forming the first integrator also includes dispensing a first core material within the first cavity. Forming the first integrator further includes forming a first set of conductive windings that at least partially encircle the first core material within the first cavity.

Another example provides an apparatus that includes a first substrate, an integrated circuit (IC) device coupled to the first substrate, and an inductive device disposed between the first substrate and the IC device. The inductive device includes a second substrate that includes a first integrated inductor. The first integrated inductor includes a first core material disposed within a first cavity of the second substrate and a first set of conductive windings that at least partially encircle the first core material within the first cavity.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a cross-sectional profile view of an exemplary device that includes an inductive device including an integrated inductor.

FIG. 2A illustrates a cross-sectional profile view of an exemplary multi-phase solenoid inductive device that includes multiple integrated inductors.

FIG. 2B illustrates a top view of the exemplary multi-phase solenoid inductive device of FIG. 2A.

FIG. 2C illustrates a more detailed cross-sectional profile view of the exemplary multi-phase solenoid inductive device of FIG. 2A.

FIG. 3A illustrates a cross-sectional profile view of another exemplary multi-phase solenoid inductive device that includes multiple integrated inductors.

FIG. 3B illustrates a top view of the exemplary multi-phase solenoid inductive device of FIG. 3A.

FIG. 3C illustrates a more detailed cross-sectional profile view of the exemplary inductive device of FIG. 3A.

FIG. 4 illustrates a top view of an exemplary multi-phase toroidal inductive device that includes multiple integrated inductors.

FIG. 5 illustrates a cross-sectional profile view of a particular implementation of a device that includes an exemplary inductive device that includes multiple integrated inductors.

FIG. 6A illustrates a first part of an exemplary sequence for fabricating an exemplary device that includes an inductive device including an integrated inductor.

FIG. 6B illustrates a second part of an exemplary sequence for fabricating an exemplary device that includes an inductive device including an integrated inductor.

FIG. 6C illustrates a third part of an exemplary sequence for fabricating an exemplary device that includes an inductive device including an integrated inductor.

FIG. 6D illustrates a fourth part of an exemplary sequence for fabricating an exemplary device that includes an inductive device including an integrated inductor.

FIG. 7 illustrates an exemplary flow diagram of a method of semiconductor fabrication for a device that includes an inductive device including an integrated inductor.

FIG. 8 illustrates various electronic devices that may integrate an inductive device including an integrated inductor described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

As used herein, the terms “comprise,” “comprises,” and “comprising” may be used interchangeably with “include,” “includes,” or “including. ” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element. As used herein, the term “coupled” refers to components that are directly coupled (i.e., touching or in direct contact) and to components that are indirectly coupled (i.e., one or more intermediate components are disposed between the coupled components). Such components may be electrically coupled either directly (i.e., a conductive path is formed between the coupled components without any intermediate components in between the coupled components) or indirectly (i.e., a conductive path is formed from one coupled component to the other through one or more intermediate components).

Improvements in manufacturing technology and demand for lower cost and more capable electronic devices has led to increasing complexity of ICs. Often, more complex ICs have more complex interconnection schemes to enable interaction between ICs of a device. The number of interconnect levels for circuitry has substantially increased due to the large number of devices that are now interconnected in a state-of-the-art mobile application device.

These interconnections include back-end-of-line (BEOL) interconnect layers, which may refer to the conductive interconnect layers for electrically coupling to front end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle of-line (MOL) interconnect layers, which interconnect to the FEOL active devices of an IC.

State-of-the-art mobile application devices demand a small form factor, low cost, a tight power budget, and high electrical performance. Mobile package design has evolved to meet these divergent goals for enabling mobile applications that support multimedia enhancements. For example, fan-out (FO) wafer level packaging (WLP) or FO-WLP process technology is a development in packaging technology that is useful for mobile applications. This chip first FO-WLP process technology solution provides flexibility to fan-in and fan-out connections from a die to package balls. In addition, this solution also provides a height reduction of a first level interconnect between the die and the package balls of mobile application devices. These mobile applications, however, are susceptible to power and signal routing issues when multiple dies are arranged within the small form factor.

Stacked die schemes and chiplet architectures are becoming more common as significant power performance area (PPA) yield enhancements are demonstrated for stacked die and chiplet architecture product lines. As used herein, “stacked dies” and/or “stacked ICs” refer to arrangements in which one die (e.g., a first die) is disposed over (including directly over) another die (e.g., a second die). As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

As IC technology advances, operating criteria for ICs of mobile devices become narrower. As one example, advanced power management integrated circuits (PMICs) can be associated with narrow signal phase delta criteria for the voltage regulators, in some cases as low as five degrees or less. Unfortunately, process variations associated with surface mount device (SMD) inductors are typically large enough that many SMD inductors are incapable of satisfying the signal phase delta criteria of PMICs, which results in increased costs to perform bin-sorting and low yield for SMD inductor fabrication.

Aspects of the present disclosure are directed to inductive devices that include one or more integrated inductors that satisfy criteria associated with various IC devices, such as PMICs. In some aspects, an inductive device includes a substrate that includes one or more integrated inductors. Each of the integrated inductors includes a respective core material disposed within a respective cavity of the substrate and a respective set of conductive windings that at least partially encircle the core material within the cavity. The inductive device has a compact size and can be disposed between a PMIC and a PCB within a mobile device or other system, thereby providing inductors for voltage regulators without increasing surface areas of the PMIC or the PCB. In some examples, the inductive device includes multiple integrated inductors that are part of a multi-phase buck regulator of the PMIC. Characteristics of the multi-phase buck regulator can be configured through design of the integrated inductors, such as selection of an inductor type (e.g., solenoidal or toroidal), selection of core material, design of the conductive windings, or a combination thereof. The disclosed inductive device with the integrated inductors provides inductors for voltage regulators that have smaller process variations than SMD inductors, and thus have higher yields and are capable of satisfying criteria associated with advanced PMICs without requiring expensive and time-consuming bin-sorting processes.

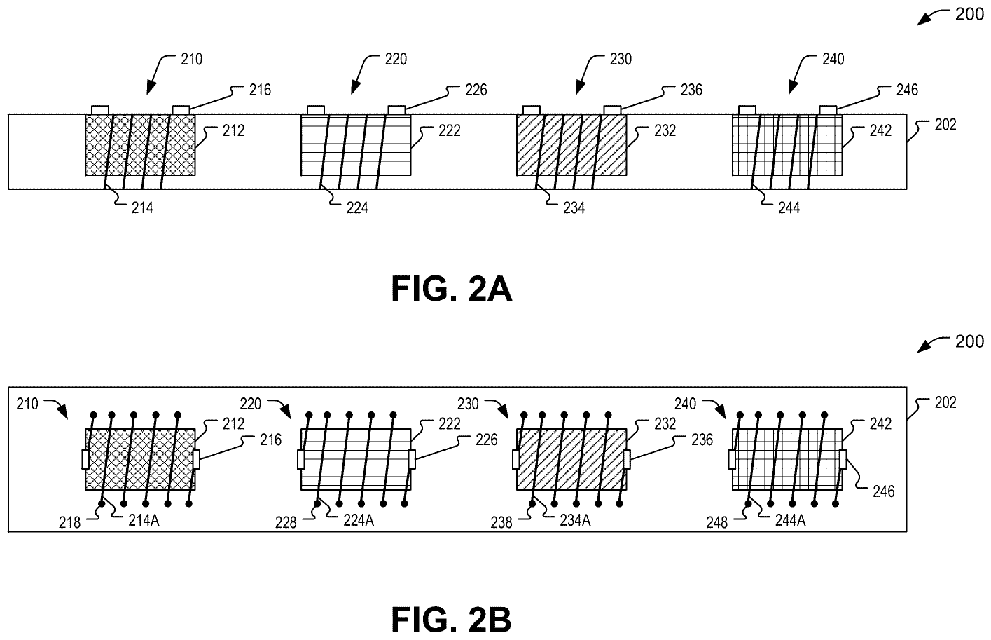

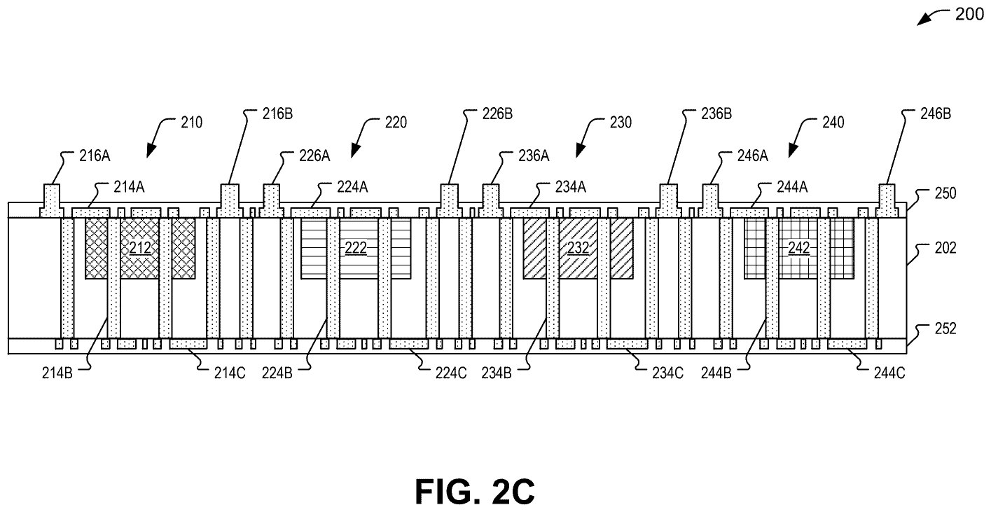

In some drawings, multiple instances of a particular type of feature are used. Although these features are physically and/or logically distinct, the same reference number is used for each, and the different instances are distinguished by addition of a letter to the reference number. When the features as a group or a type are referred to herein e.g., when no particular one of the features is being referenced, the reference number is used without a distinguishing letter. However, when one particular feature of multiple features of the same type is referred to herein, the reference number is used with the distinguishing letter. For example, referring to FIG. 2C, multiple external connectors 216 are illustrated and associated with reference numbers 216A and 216B. When referring to a particular one of these external connectors, such as an external connector 216A, the distinguishing letter “A” is used. However, when referring to any arbitrary one of these external connectors or to these external connectors as a group, the reference number 216 is used without a distinguishing letter.

### Exemplary Inductive Device Including Integrated Inductor(s)

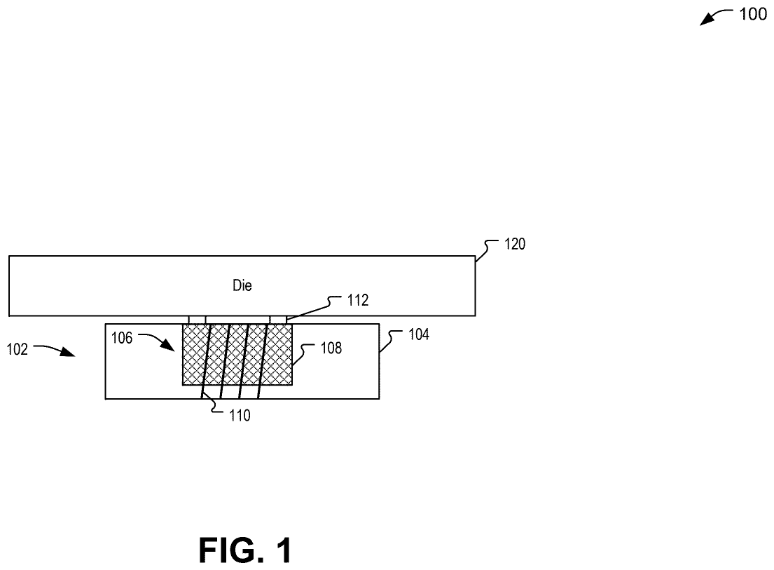

FIG. 1 illustrates a cross-sectional profile view of an exemplary device 100 that includes an inductive device including an integrated inductor. In the implementation shown in FIG. 1, the device 100 includes an inductive device 102 and a die 120. In other examples, the device 100 can include one or more additional components, such as a PCB, one or more additional dies, other components, or a combination thereof.

The die 120 can include integrated circuitry, such as a plurality of transistors and/or other circuit elements arranged and interconnected to form logic cells, memory cells, etc. Components of the integrated circuitry can be formed in and/or over a semiconductor substrate. Different implementations can use different types of transistors, such as a field effect transistor (FET), planar FET, finFET, a gate all around FET, or mixtures of transistor types. In some implementations, a front end-of-line (FEOL) process may be used to fabricate the integrated circuitry in and/or over the semiconductor substrate of the die 120. In some implementations, the die 120 is configured to be electrically coupled to a PCB or another substrate, as further described herein.

The die 120 may include or correspond to a particular IC device that can be arranged and interconnected with other IC devices as a three-dimensional (3D) IC device. In some implementations, the die 120 includes a microcontroller, an application specific integrated circuit (ASIC), a field programmable gate arrays (FPGA), a central processing unit (CPU) having one or more processing cores, a processing system, a system on chip (SoC), or other circuitry and logic configured to facilitate the operations of the die 120. Additionally, or alternatively, the die 120 may include or be operated as a memory, such as a static random-access memory (SRAM), a dynamic random-access memory (DRAM), flash memory, read-only memory (ROM), programmable read-only memory (PROM), erasable programmable read-only memory (EPROM), electrically erasable programmable read-only memory (EEPROM), a solid-state storage device (SSD), or a combination thereof. In some other examples, the die 120 includes or is operated as another type of integrated circuit, such as a power management integrated circuit (PMIC).

The inductive device 102 includes one or more inductors that are integrated within the inductive device 102, referred to herein as integrated inductor(s). In the example shown in FIG. 1, the inductive device 102 includes a substrate 104 and an integrated inductor 106 (e.g., a first integrated inductor). The exemplary inductive device 102 shown in FIG. 1 is not intended to be limiting, and in other implementations, the inductive device 102 includes multiple integrated inductors, as further described herein with referent to FIGS. 2-4. The substrate 104 may include alumina, glass, high-resistivity (HR) silicon, or another substance in which through-substrate vias and blind via cavities may be formed. In some examples, a thickness of the substrate 104 is 100-200 microns.

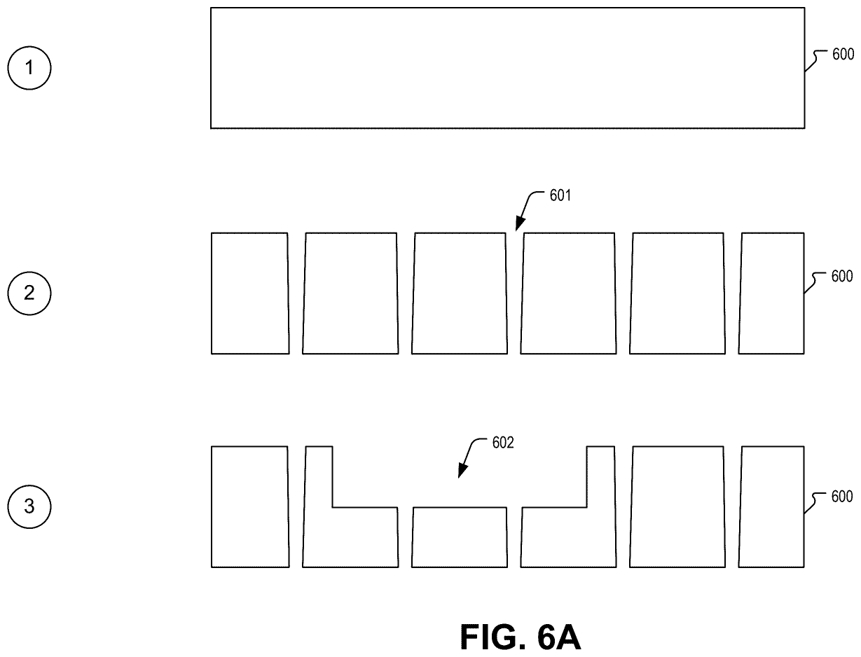

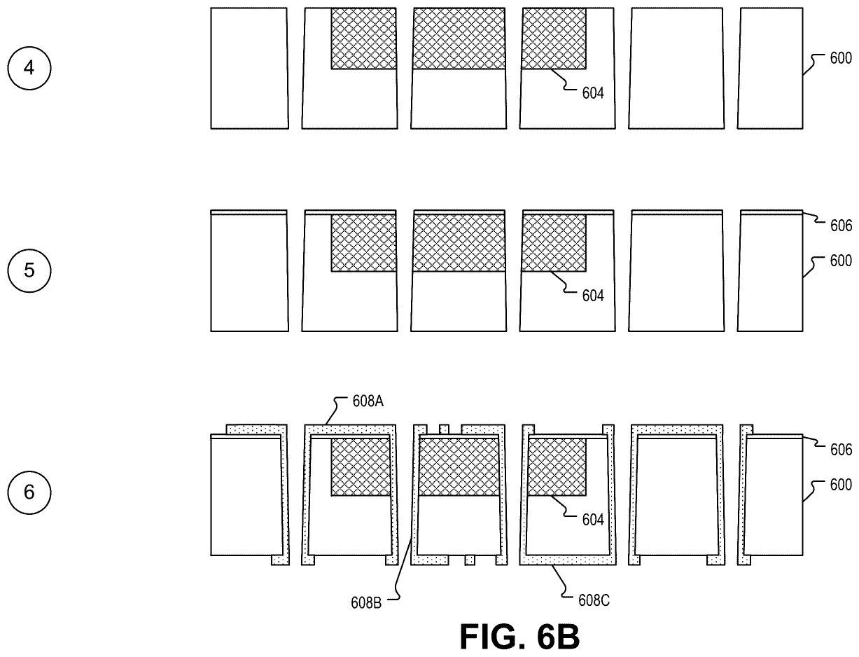

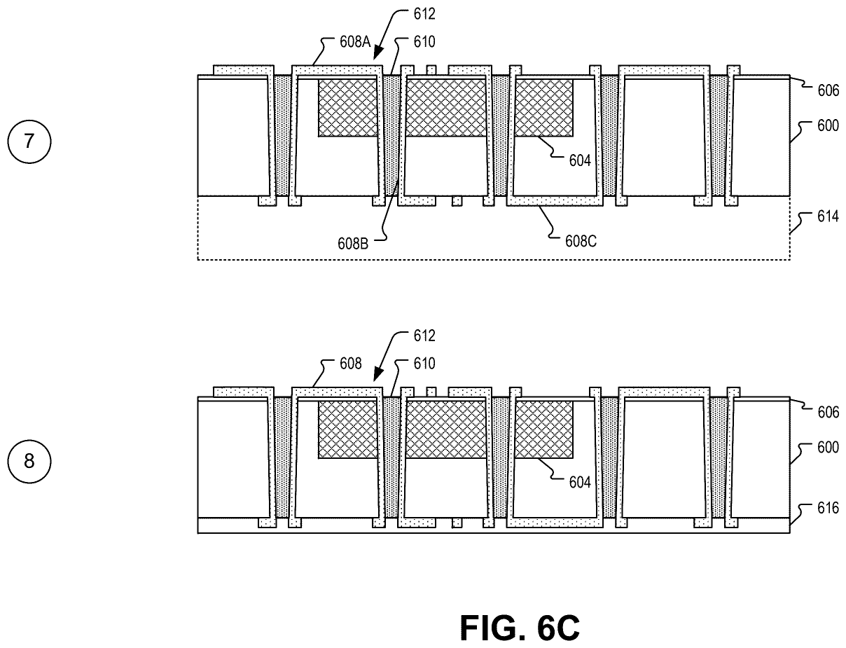

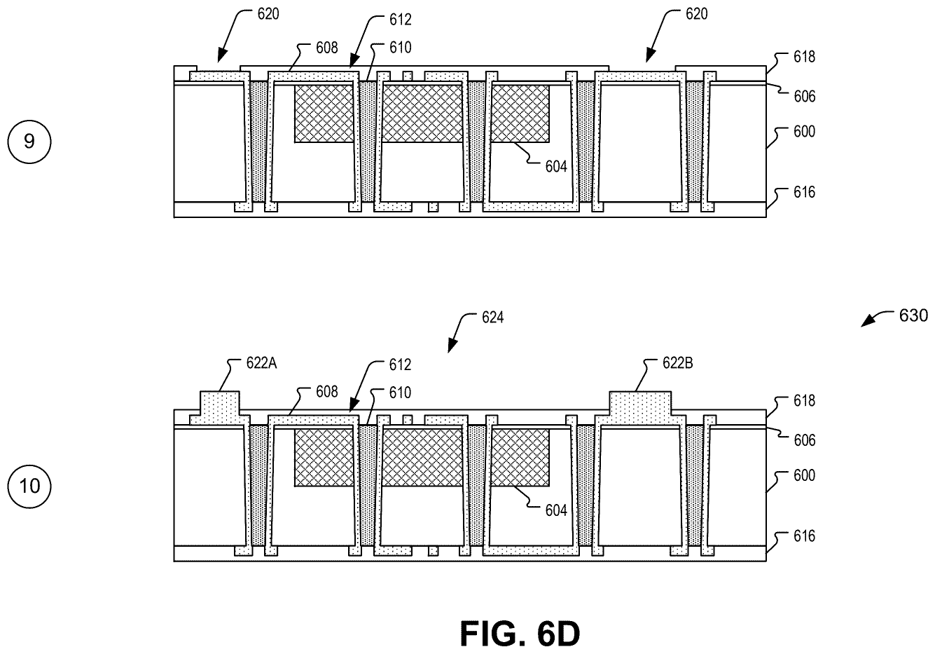

The integrated inductor 106 may include a core material 108 that is disposed within a cavity of the substrate 104 and a set of conductive windings 110 that at least partially encircle the core material 108 within the cavity. For example, during fabrication of the inductive device 102, a cavity may be formed in the substrate 104 and the core material 108 may be dispensed or otherwise deposited within the cavity, as further described herein with reference to FIGS. 6A-6D. The core material 108 may include a magnetic filler material, such as ferrite material, magnetic or ferrous powders, iron or iron alloy, other ferromagnetic or ferrimagnetic materials, or the like. Alternatively, the core material 108 may include a non-magnetic filler material, such as ceramics or ceramic materials. The conductive windings 110 may include one or more metal layers within the substrate 104 and conductive material within one or more vias (e.g., one or more through-substrate vias (TSuVs)) within the substrate 104. As used herein, TSuVs include vias that extend through one or more dies, such as through-silicon vias that extend through 3D stacked dies, and vias that extend through a packaging substrate, such as the substrate 104, which can include other materials instead of silicon. The metal layers and the conductive material may be electrically coupled to form the set of conductive windings 110 that at least partially encircle the core material 108 within the cavity of the substrate 104.

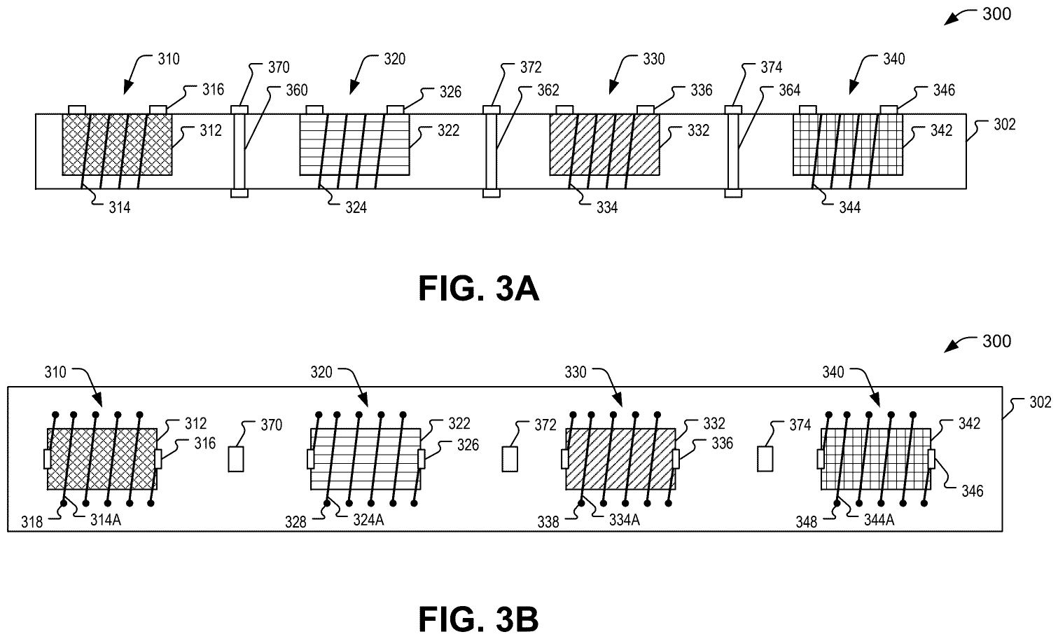

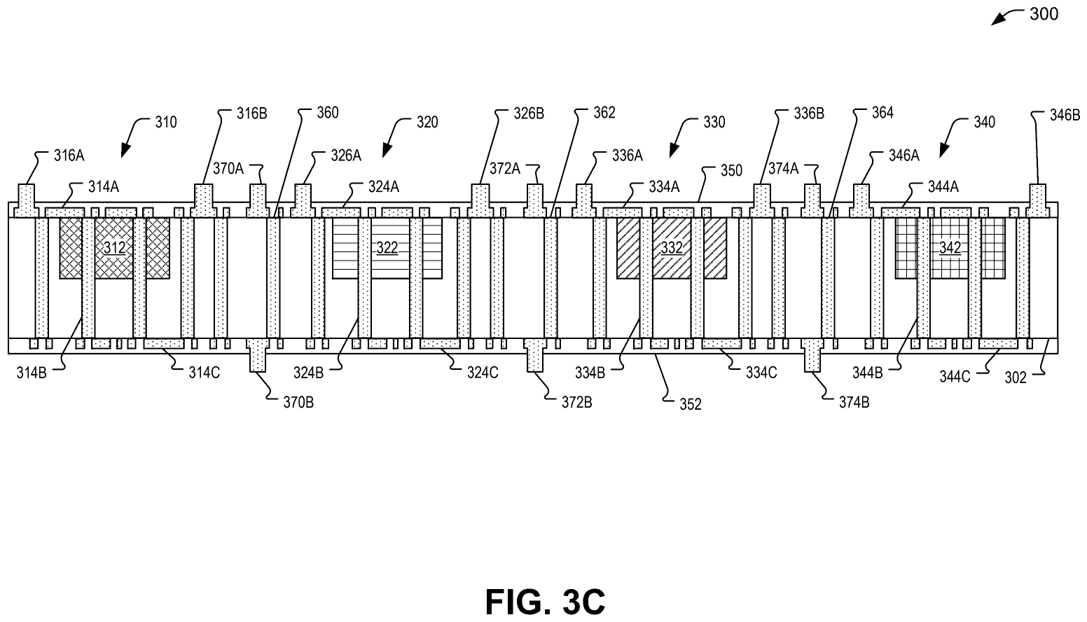

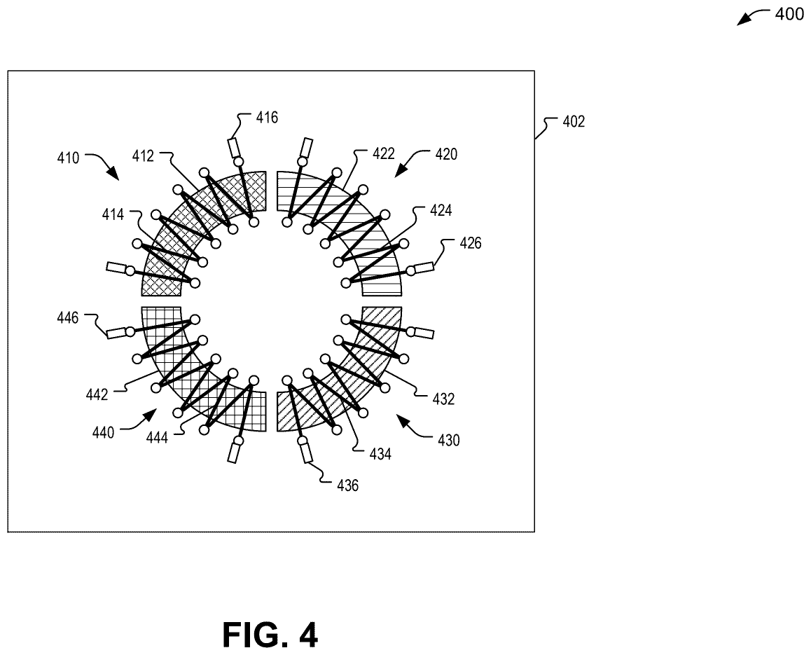

In some examples in which the inductive device 102 includes multiple integrated inductors (e.g., including the integrated inductor 106), the inductive device 102 may include or correspond to a multi-phase inductor. As used herein, multiple integrated inductors that are included in a multi-phase inductor may be referred to as a multi-phase integrated inductor (MPII). Such a multi-phase integrated inductor may be included in or used by a multi-phase buck regulator that is implemented by the die 120, which may include or be configured to operate as a PMIC. Additionally, or alternatively, the inductive device 102 (e.g., the multi-phase inductor) may be designed to have a shape that is selected based on various design considerations and operating criteria of the die 120. In some examples, the inductive device 102 includes multiple integrated inductors that extend along a common axis in a particular direction to form a multi-phase solenoid inductor (e.g., an inductor having a solenoid shape), as further described herein with reference to FIGS. 2A-3C. In some other examples, the inductive device 102 includes multiple integrated inductors that extend along a loop to form a multi-phase toroidal inductor (e.g., an inductor having a toroidal shape), as further described herein with reference to FIG. 4. The multi-phase toroidal inductor may occupy less area than the multi-phase solenoid inductor (e.g., have a more compact size with respect to the die 120).

A set of external connectors 112 may electrically couple the integrated inductor 106 to the die 120 by providing conductive pathway(s) between the integrated inductor 106 and the die 120. For example, the external connectors 112 (e.g., one or more contacts or interconnects) may electrically couple the integrated inductor 106 to one or more contacts, pads, or other interconnects of the die 120. Any of the conductive interconnects and contacts described herein can include, for example, microbumps, conductive pillars, conductive pads (e.g., for pad-to-pad bonding), or other similar chiplet-to-chiplet interconnect contacts used for 3D chiplet stacking.

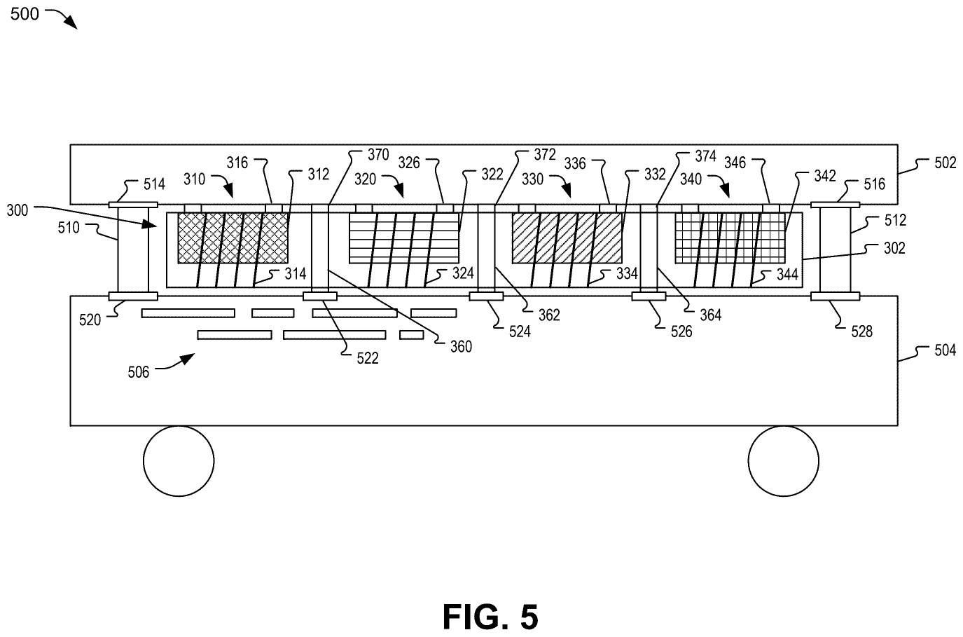

In some examples, the external connectors 112 are disposed on a first side (e.g., a top side) of the substrate 104, and the inductive device 102 can include additional connectors (not shown in FIG. 1) that provide conductive pathways between the die 120 and a PCB or other component coupled to a second side (e.g., a bottom side) of the substrate 104. In a particular example, the inductive device 102 includes a second set of external connectors that are disposed on the same side of the substrate 104 as the external connectors 112 and that are configured to be coupled to one or more contacts or pads of the die 120. Continuing this particular example, the inductive device 102 also includes a third set of external contacts that are disposed on the opposite side of the substrate 104 and that are configured to be coupled to one or more contacts or pads of the PCB or other component. Conductive pathways between the die 120 and the PCB or other component may be provided by the second and third sets of external contacts and one or more TSuVs between corresponding pairs of contacts within the substrate 104, as further described with reference to FIGS. 3A-3C and 5.

In a particular implementation, the device 100 includes a substrate (e.g., the substrate 104) that includes a first integrated inductor (e.g., the integrated inductor 106). The first integrated inductor includes a first core material (e.g., the core material 108) disposed within a first cavity of the substrate and a first set of conductive windings (e.g., the conductive windings 110) that at least partially encircle the first core material within the first cavity.

It should be understood that the device 100 may include additional components, other components, fewer components, or a combination thereof, to support the functionality described herein. As non-limiting examples, the device 100 may include additional IC devices, additional layers, additional dies, additional packages, additional interconnects, additional structures, other components, different components, or a combination thereof, to support the functionality and technical advantages disclosed herein.

During operation of the device 100, the integrated inductor 106 may be coupled to the die 120 to provide a passive inductance as part of a voltage regulator, such as a multi-phase buck regulator. In some examples, the die 120 may operate as a PMIC and provide step-up or step-down voltages, using the voltage regulator that includes the integrated inductor 106, to other components of the device 100 (not shown). One or more characteristics of the integrated inductor 106, or components thereof, may be selected during design or fabrication such that the integrated inductor 106 has a target inductance, a target quality-factor (Q-factor), or both, during operation of the device 100. For example, a width, a depth, or both, of the cavity in which the integrated inductor 106 is formed may be chosen to achieve the target inductance, the target Q-factor, or both. As another example, a type of the core material 108 (e.g., a material type, a magnetic or non-magnetic type, a permeability, etc.) may be chosen to achieve the target inductance, the target Q-factor, or both. As another example, a length of the conductive windings 110, a number of windings included in the conductive windings 110, a material used to form the conductive windings 110, or the like, may be chosen to achieve the target inductance, the target Q-factor, or both.

The inductive device 102 thus provides inductor(s) for voltage regulators that have higher yield and that can satisfy more narrow operational criteria than discrete SMD inductors of other voltage regulators. For example, because the integrated inductor 106 (and any additional inductors included in the inductive device 102) is a 3D inductor formed in a substrate during a single fabrication process, the integrated inductor 106 (and other integrated inductors) has fewer process variations than individually fabricated SMD inductors. These fewer process variations enable the integrated inductor to support voltage signals having lower signal phase deltas, such as less than five degrees, as compared to the approximately twenty-degree signal phase deltas that are often exhibited by typical SMD inductors. Because the integrated inductor 106 supports lower signal phase deltas, the integrated inductor 106 may satisfy criteria associated with operation of a PMIC (e.g., the die 120), thereby enabling the inductive device 102 to be part of a multi-phase bulk regulator that provides power to advanced IC device components of the device 100 without the additional cost and time associated with performing bin sorting of SMD inductors to compensate for low yield caused by process variations. The inductive device 102 may achieve improved or optimized voltage regulation with segmented low-variation individual inductors within a compact chip area. A technical advantage of the inductive device 102 is that the inductive device 102 supports multi-phase buck regulators or other voltage regulators having narrow operating criteria in a cost-effective and compact (e.g., with respect to chip area) solution that has a higher yield than typical SMD inductors.

Referring to FIGS. 2A-2C, FIG. 2A illustrates a cross-sectional profile view of an exemplary multi-phase solenoid inductive device 200 (referred to herein as “the inductive device 200”) that includes multiple integrated inductors. FIG. 2B illustrates a top view of the inductive device 200 of FIG. 2A. FIG. 2C illustrates a more detailed cross-section profile view of the inductive device 200 of FIG. 2A. In some implementations, the inductive device 200 includes or corresponds to the inductive device 102 of FIG. 1.

In the example shown in FIG. 2A, the inductive device 200 includes a substrate 202, a first integrated inductor 210, a second integrated inductor 220, a third integrated inductor 230, and a fourth integrated inductor 240. In other examples, the inductive device 200 may include fewer than four integrated inductors or more than four integrated inductors. The integrated inductors 210, 220, 230, and 240 may be a multi-phase integrated inductor (MPII) that is part of a buck regulator or other voltage regulator, such as for a PMIC. The substrate 202 may include or correspond to the substrate 104 of FIG. 1.

Each of the integrated inductors 210, 220, 230, and 240 include a corresponding core material disposed within a corresponding cavity (e.g., a blind cavity) of the substrate 202 and a corresponding set of conductive windings that at least partially encircle the corresponding core material within the corresponding cavity. For example, the first integrated inductor 210 includes a first core material 212 disposed within a first cavity of the substrate 202 and a first set of conductive windings 214 that at least partially encircle the first core material 212 within the first cavity. As another example, the second integrated inductor 220 includes a second core material 222 disposed within a second cavity of the substrate 202 and a second set of conductive windings 224 that at least partially encircle the second core material 222 within the second cavity. Similarly, the third integrated inductor 230 includes a third core material 232 disposed within a third cavity of the substrate 202 and a third set of conductive windings 234 that at least partially encircle the third core material 232 within the third cavity, and the fourth integrated inductor 240 includes a fourth core material 242 disposed within a fourth cavity of the substrate 202 and a fourth set of conductive windings 244 that at least partially encircle the fourth core material 242 within the fourth cavity.

Each of the core materials 212, 222, 232, and 242 may include various materials to provide an inductor core to the respective one of the integrated inductors 210, 220, 230, and 240. In some examples, the core materials 212, 222, 232, and 242 include various magnetic filler materials, such as ferrite material, magnetic or ferrous powders, iron or iron alloy, other ferromagnetic or ferrimagnetic materials, or the like. Alternatively, one or more of the core materials 212, 222, 232, and 242 may include non-magnetic filler materials, such as ceramics or ceramic materials. In some examples, the core materials 212, 222, 232, and 242 include the same material (e.g., the same magnetic filler material or the same non-magnetic filler material). In some other examples, one or more of the core materials 212, 222, 232, and 242 includes different materials than other(s) of the core materials 212, 222, 232, and 242. In the example shown in FIG. 2A, the first core material 212, the second core material 222, the third core material 232, and the fourth core material 242 each include a different type of material.

The conductive windings 214, 224, 234, and 244 may include copper or another conductive material, and each of conductive windings 214, 224, 234, and 244 may at least partially encircle the corresponding core material 212, 222, 232, or 242, within the respective cavities of the substrate 202. In some aspects, the conductive windings 214, 224, 234, and 244 each include multiple respective conductive lines on opposite surfaces (e.g., a first surface and a second surface) of the substrate 202 and portions that include conductive material disposed within respective sets of TSuVs that extend between the first surface and the second surface of the substrate 202 (e.g., TSuVs that extend through a packaging substrate). The various conductive lines and conductive materials are illustrated in the examples depicted in FIGS. 2B-2C. To illustrate, FIG. 2B shows that the first set of conductive windings 214 include a first set of conductive lines 214A on the first surface (e.g., a top surface) of the substrate 202 and coupled to a first set of TSuVs 218 that extend between the first surface and the second surface of the substrate 202. FIG. 2C shows that the first set of conductive windings 214 include a second set of conductive lines 214C on the second surface (e.g., a bottom surface) of the substrate 202 and coupled to a first set of TSuVs 218, and conductive material 214B within the first set of TSuVs 218. Similarly, the second set of conductive windings 224 include a first set of conductive lines 224A on the top surface, a second set of conductive lines 224C on the bottom surface, and conductive material 224B within a second set of TSuVs 228 that extend between the top surface and the bottom surface, a third set of conductive windings 234 include a first set of conductive lines 234A on the top surface, a second set of conductive lines 234C on the bottom surface, and conductive material 234B within a third set of TSuVs 238 that extend between the top surface and the bottom surface, and a fourth set of conductive windings 244 include a first set of conductive lines 244A on the top surface, a second set of conductive lines 244C on the bottom surface, and conductive material 244B within a fourth set of TSuVs 248 that extend between the top surface and the bottom surface. As shown in FIG. 2C, the conductive lines 214A, 224A, 234A, and 244A on the top surface may be covered with a top dielectric layer 250, and the conductive lines 214C, 224C, 234C, and 244C may be covered with a bottom dielectric layer 252. An example of formation of conductive lines and conductive materials within TSuVs is further described herein with reference to FIGS. 6A-6D.

The integrated inductors 210, 220, 230, and 240 may include respective sets of external connectors. For example, the first integrated inductor 210 may include first external connectors 216, the second integrated inductor 220 may include second external connectors 226, the third integrated inductor 230 may include third external connectors 236, and the fourth integrated inductor 240 may include fourth external connectors 246. The external connectors 216, 226, 236, and 246 may be configured to electrically couple the respective integrated inductor of the integrated inductors 210, 220, 230, and 240 to another device (e.g., an IC device, such as a PMIC). In some examples, each of the external connectors 216, 226, 236, and 246 include two connectors that are configured to electrically couple a first terminal and a second terminal of the respective integrated inductor to the other device or component. For example, the first external connectors 216 may include an external connector 216A configured to electrically couple a first terminal of the first integrated inductor 210 to the other device or component and an external connector 216B configured to electrically couple a second terminal of the first integrated inductor 210 to the other device or component. The sets of external connectors 226, 236, and 246 may similarly include external connectors 226A and 226B, 236A and 236B, and 246A and 246B, respectively.

In some examples, the integrated inductors 210, 220, 230, and 240 are arranged in a solenoid configuration. For example, each respective cavity and each respective set of conductive windings 214, 224, 234, and 244 of the integrated inductors 210, 220, 230, and 240 extend along a common axis in a particular direction within the substrate 202 to form a multi-phase solenoid inductor. In such an example, each of the integrated inductors 210, 220, 230, and 240 may be inductively coupled together. In some such examples, the inductive device 200 is configured as an MPII for multi-phase bulk regulators. In other examples, the integrated inductors 210, 220, 230, and 240 may each be discrete inductors that are not inductively coupled together.

Characteristics and parameters of the integrated inductors 210, 220, 230, and 240 may be determined during a design process of the inductive device 200 to enable the integrated inductors 210, 220, 230, and 240 to have low signal phase deltas so that that the integrated inductors 210, 220, 230, and 240 may be configured as part of multiple voltage regulators for a PMIC or another IC device. As an example, target inductances and Q-factors may be achieved by selection of the core material (e.g., the core materials 212, 222, 232, and 242) to fill each of the blind substrate cavities to form the integrated inductors 210, 220, 230, and 240. In some examples, different integrated inductors of the integrated inductors 210, 220, 230, and 240 may include different magnetic or non-magnetic fill materials having different permeabilities. Additionally, or alternatively, each of the integrated inductors 210, 220, 230, and 240 may include 2-sided redistribution layer (RDL) wiring (e.g., the conductive windings 214, 224, 234, and 244) extending across the blind substrate cavities and through the TSuVs 218, 228, 238, and 248 to form 3D integrated inductors for use with a multi-phase bulk regulator of a PMIC.

Referring to FIGS. 3A-3C, FIG. 3A illustrates a cross-sectional profile view of another exemplary multi-phase solenoid inductive device 300 (referred to herein as “the inductive device 300”) that includes multiple integrated inductors. FIG. 3B illustrates a top view of the inductive device 300 of FIG. 3A. FIG. 3C illustrates a more detailed cross-section profile view of the inductive device 300 of FIG. 3A. In some implementations, the inductive device 300 includes or corresponds to the inductive device 102 of FIG. 1.

In the example shown in FIGS. 3A-3C, the inductive device 300 includes a substrate 302, a first integrated inductor 310, a second integrated inductor 320, a third integrated inductor 330, and a fourth integrated inductor 340. The substrate 302 may include or correspond to the substrate 104 of FIG. 1 or the substrate 202 of FIGS. 2A-2C. Although the example shown in FIGS. 3A-3C includes four integrated inductors, in other examples, the inductive device 300 may include fewer than four integrated inductors or more than four integrated inductors. Each of the integrated inductors 310, 320, 330, and 340 includes a corresponding core material disposed within a corresponding cavity (e.g., a blind cavity) of the substrate 302, a corresponding set of conductive windings that at least partially encircle the corresponding core material within the corresponding cavity, and a corresponding set of external connectors, similar to the integrated inductors 210, 220, 230, and 240 of FIGS. 2A-2C. Additionally, each of the sets of conductive windings may include conductive lines on a first surface (e.g., a top surface) of the substrate 302, conductive lines on a second surface (e.g., a bottom surface) of the substrate 302, and conductive material within sets of TSuVs between the first surface and the second surface, and each set of external connectors may include a first external connector configured to electrically couple a first terminal of the corresponding integrated inductor to another device or component and a second external connector configured to electrically couple a second terminal of the corresponding integrated inductor to the other device or component. The TSuVs may extend through one or more packaging substrates that include materials other than silicon, in some examples.

For example, the first integrated inductor 310 may include a first core material 312 disposed within a first cavity of the substrate 302, a first set of conductive windings 314 that at least partially encircle the first core material 312 within the first cavity, and a first set of external connectors 316. The first set of conductive windings 314 include a first set of conductive lines 314A on the top surface, a second set of conductive lines 314C on the bottom surface, and conductive material 314B within a first set of TSuVs 318 that extend between the top surface and the bottom surface of the substrate 302. The first set of external connectors 316 may include an external connector 316A configured to electrically couple a first terminal of the first integrated inductor 310 to the other device or component and an external connector 316B configured to electrically couple a second terminal of the first integrated inductor 310 to the other device or component.

As another example, the second integrated inductor 320 may include a second core material 322 disposed within a second cavity of the substrate 302, a second set of conductive windings 324 that at least partially encircle the second core material 322 within the second cavity, and a second set of external connectors 326. The second set of conductive windings 324 include a first set of conductive lines 324A on the top surface, a second set of conductive lines 324C on the bottom surface, and conductive material 324B within a first set of TSuVs 328 that extend between the top surface and the bottom surface of the substrate 302. The second set of external connectors 326 may include an external connector 326A configured to electrically couple a first terminal of the second integrated inductor 320 to the other device or component and an external connector 326B configured to electrically couple a second terminal of the second integrated inductor 320 to the other device or component.

Similarly, the third integrated inductor 330 may include a third core material 332 disposed within a third cavity of the substrate 302, a third set of conductive windings 334 that at least partially encircle the third core material 332 within the third cavity, and a third set of external connectors 336. The third set of conductive windings 334 include a first set of conductive lines 334A on the top surface, a second set of conductive lines 334C on the bottom surface, and conductive material 334B within a first set of TSuVs 338 that extend between the top surface and the bottom surface of the substrate 302. The third set of external connectors 336 may include an external connector 336A configured to electrically couple a first terminal of the third integrated inductor 330 to the other device or component and an external connector 336B configured to electrically couple a second terminal of the third integrated inductor 330 to the other device or component.

As another example, the fourth integrated inductor 340 may include a fourth core material 342 disposed within a fourth cavity of the substrate 302, a fourth set of conductive windings 344 that at least partially encircle the fourth core material 342 within the fourth cavity, and a fourth set of external connectors 346. The fourth set of conductive windings 344 include a first set of conductive lines 344A on the top surface, a second set of conductive lines 344C on the bottom surface, and conductive material 344B within a first set of TSuVs 348 that extend between the top surface and the bottom surface of the substrate 302. The fourth set of external connectors 346 may include an external connector 346A configured to electrically couple a first terminal of the fourth integrated inductor 340 to the other device or component and an external connector 346B configured to electrically couple a second terminal of the fourth integrated inductor 340 to the other device or component.

Each of the core materials 312, 322, 332, and 342 may include a different fill material (e.g., a magnetic fill material or a non-magnetic fill material) as shown in FIGS. 3A-3C, or one or more of the core materials 312, 322, 332, and 342 may include the same fill material. In the example shown in FIG. 3C, the conductive lines 314A, 324A, 334A, and 344A on the top surface may be covered with a top dielectric layer 350 and the conductive lines 314C, 324C, 334C, and 344C may be covered with a bottom dielectric layer 352. Additionally, or alternatively, the integrated inductors 310, 320, 330, and 340 may be inductively coupled together or may each be discrete inductors. In some examples in which the integrated inductors 310, 320, 330, and 340 are inductively coupled together, the integrated inductors 310, 320, 330, and 340 may be an MPII that is part of a buck regulator or other voltage regulator, such as for a PMIC. Additionally, or alternatively, the integrated inductors 310, 320, 330, and 340 may be arranged in a solenoid configuration (e.g., an axis may extend through each of the integrated inductors 310, 320, 330, and 340 along a particular direction through the substrate 302), as described above with reference to FIGS. 2A-2C.

The example of the inductive device 300 depicted in FIGS. 3A-3C has a double bump configuration and can act as an interposer device that provides conductive pathways between devices or components on opposite sides of the inductive device 300, as compared to the example of the inductive device 200 of FIGS. 2A-2C that has a single bump configuration. To illustrate, the inductive device 300 also includes external connectors and conductive material within TSuVs that are configured to electrically couple a device above the inductive device 300 (e.g., a device that is adjacent to the top surface) to a device below the inductive device 300 (e.g., a device that is adject to the bottom surface). For example, the inductive device 300 may include external connectors 370 and a conductive material within a TSuV 360 that are disposed between the first integrated inductor 310 and the second integrated inductor 320, external connectors 372 and a conductive material within a TSuV 362 that are disposed between the second integrated inductor 320 and the third integrated inductor 330, and external connectors 374 and a conductive material within a TSuV 364 that are disposed between the third integrated inductor 330 and the fourth integrated inductor 340. Although three sets of external connectors 370, 372, and 374 and conductive material within three TSuVs 360, 362, and 364 are shown in FIG. 3C, in other examples, the inductive device 300 may include more than three or fewer than three sets of external connectors and TSuVs that include conductive material.

In the example shown in FIGS. 3A-3C, the inductive device 300 includes multiple sets of external connectors on each of the top and bottom surfaces of the substrate 302. Some of these external connectors that are disposed on the top surface are configured to electrically couple the integrated inductors 310, 320, 330, and 340 to a first external device (e.g., a PMIC or other IC device) that is above the inductive device 300. For example, the inductive device 300 includes the external connectors 316A and 316B, of the first set of external connectors 316, that are disposed on a first surface (e.g., a top surface) of the substrate 302, coupled to the first integrated inductor 310, and configured to be coupled to a first external device (e.g., above the inductive device 300). The inductive device 300 may also include additional sets of external connectors (e.g., the sets of external connectors 326, 336, and 346) disposed on the top surface and configured to be coupled to the first external device.

Others of the external connectors are configured to electrically couple the first external device, through conductive pathways that include the conductive material in some of the TSuVs and the external connectors on the bottom surface, to a second external device (e.g., a PCB or another IC device) that is below the inductive device 300. For example, the inductive device 300 includes a second set of external connectors (including external connectors 370A, 372A, and 374A) disposed on the first surface of the substrate 302, a third set of external connectors (including external connectors 370B, 372B, and 374B) disposed on a second surface (e.g., a bottom surface) of the substrate 302 that is opposite of the first surface, and TSuVs 360, 362, and 364 that extend between corresponding connectors from the second set of external connectors and the third set of external connectors. In a particular example, the external connectors 370A, 372A, and 374A, the external connectors 370B, 372B, and 374B, and the TSuVs 360, 362, and 364, are configured to provide respective conductive pathways between the first external device and the second external device. To illustrate, the external connector 370A may be configured to be coupled to the first external device, the external connector 370B may be configured to be coupled to the second external device, and the TSuV 360 may extend between the external connector 370A and the external connector 370B. To further illustrate, additional sets of external connectors (e.g., the external connectors 372A and 374A may be configured to be coupled to the first external device, additional sets of external connectors (e.g., the external connectors 372B and 374B) may be configured to be coupled to the second external device, and additional sets of TSuVs (e.g., the TSuVs 362 and 364) may extend between corresponding external connectors on the top and bottom surfaces. Thus, the external connectors 370-374 and the TSuVs 360-362 may establish conductive pathways between the first external device and the second external device, and the external connectors 316, 326, 336, and 346 may establish conductive pathways between the integrated inductors 310, 320, 330, and 340, respectively, and the first external device.

FIG. 4 illustrates a top view of an exemplary multi-phase toroidal inductive device 400 (referred to herein as “the inductive device 400”) that includes multiple integrated inductors. In some implementations, the inductive device 400 includes or corresponds to the inductive device 102 of FIG. 1. In the example shown in FIG. 4, the inductive device 400 includes a substrate 402, a first integrated inductor 410, a second integrated inductor 420, a third integrated inductor 430, and a fourth integrated inductor 440. The substrate 402 may include or correspond to the substrate 104 of FIG. 1, the substrate 202 of FIGS. 2A-2C, or the substrate 302 of FIGS. 3A-3C. Although the example shown in FIG. 4 includes four integrated inductors, in other examples, the inductive device 400 may include fewer than four integrated inductors or more than four integrated inductors.

Each of the integrated inductors 410, 420, 430, and 440 include a corresponding core material disposed within a corresponding cavity (e.g., a blind cavity) of the substrate 402, a corresponding set of conductive windings that at least partially encircle the corresponding core material within the corresponding cavity, and a corresponding set of external connectors, similar to the integrated inductors 210, 220, 230, and 240 of FIGS. 2A-2C and the integrated inductors 310, 320, 330, and 340 of FIGS. 3A-3C. For example, the first integrated inductor 410 may include a first core material 412 disposed within a first cavity of the substrate 402, a first set of conductive windings 414 that at least partially encircle the first core material 412 within the first cavity, and a first set of external connectors 416. As another example, the second integrated inductor 420 may include a second core material 422 disposed within a second cavity of the substrate 402, a second set of conductive windings 424 that at least partially encircle the second core material 422 within the second cavity, and a second set of external connectors 426. Similarly, the third integrated inductor 430 may include a third core material 432 disposed within a third cavity of the substrate 402, a third set of conductive windings 434 that at least partially encircle the third core material 432 within the third cavity, and a third set of external connectors 436, and the fourth integrated inductor 440 may include a fourth core material 442 disposed within a fourth cavity of the substrate 402, a fourth set of conductive windings 444 that at least partially encircle the fourth core material 442 within the fourth cavity, and a fourth set of external connectors 446.

Each of the core materials 412, 422, 432, and 442 may include a different fill material (e.g., a magnetic fill material or a non-magnetic fill material) as shown in FIG. 4, or one or more of the core materials 412, 422, 432, and 442 may include the same fill material. Additionally, or alternatively, each of the sets of conductive windings 414, 424, 434, and 444 may include conductive lines on a first surface (e.g., a top surface) of the substrate 402, conductive lines on a second surface (e.g., a bottom surface) of the substrate 402, and conductive material within sets of TSuVs between the first surface and the second surface, and each set of external connectors may include an external connector configured to electrically couple a first terminal of the corresponding integrated inductor to another device or component and an external connector configured to electrically couple a second terminal of the corresponding integrated inductor to the other device or component, as described above with reference to FIGS. 2A-2C and FIGS. 3A-3C.

The integrated inductors 410, 420, 430, and 440 may be inductively coupled together or may each be discrete inductors. In some examples in which the integrated inductors 410, 420, 430, and 440 are inductively coupled together, the integrated inductors 410, 420, 430, and 440 may be an MPII that is part of a buck regulator or other voltage regulator, such as for a PMIC. In contrast to the inductive device 200 of FIGS. 2A-2C and the inductive device 300 of FIGS. 3A-3C, the inductive device 400 of FIG. 4 may be arranged in a toroidal configuration. To illustrate, each respective cavity (or the core materials 412, 422, 432, and 442 disposed within the cavities) and each respective set of the sets of conductive windings 414, 424, 434, and 444 extend along a loop within the substrate 402 to form a multi-phase toroidal inductor. Due to the toroidal configuration, the inductive device 400 may be smaller or take up less chip space than the inductive device 200 of FIGS. 2A-2C or the inductive device 300 of FIGS. 3A-3C, which each have a solenoid configuration.

### Exemplary Integrated Device Including an Inductive Device that Includes Integrated Inductor(s)

FIG. 5 illustrates a cross-sectional profile view of a particular implementation of a device 500 that includes the exemplary inductive device 300 of FIGS. 3A-3C, which may include or correspond to the inductive device 102 of FIG. 1. The device 500 of FIG. 5 includes many of the same components and features as are described above with reference to FIGS. 3A-3C. Such components and features are physically and operationally the same as described above with reference to FIGS. 3A-3C and are labeled in FIG. 5 using the same reference numbers. In some implementations, the device 500 includes all of the same features and components as the inductive device 300 of FIGS. 3A-3C; however, some components and features illustrated in FIGS. 3A-3C have been omitted from (or are not labeled with reference numbers in) FIG. 5 for simplicity of illustration and to highlight differences between the device 100 and the device 500. Omission of such features and reference numbers should not be understood as limiting the features and components of FIG. 5 to only those specifically called out below. For example, while FIG. 5 does not show the sets of TSuVs 318, 328, 338, and 348 of FIG. 3B, the device 500 can include the sets of TSuVs 318, 328, 338, and 348 (e.g., in a different view). The example depicted in FIG. 5 is for illustration and is not intended to be limiting. In other examples, the device 500 may include the inductive device 200 of FIGS. 2A-2C or the inductive device 400 of FIG. 4 in place of the inductive device 300.

In the example shown in FIG. 5, the device 500 includes an IC device 502, a PCB 504 coupled to the IC device 502, and the inductive device 300 disposed between the PCB 504 and the IC device 502. The IC device 502 may include a die or other IC that is configured to perform one or more operations. In some examples, the IC device 502 includes a PMIC that includes a multi-phase buck regulator coupled to integrated inductors of the inductive device 300. The PCB 504 includes a substrate that includes dielectric material(s) surrounding one or more conductive layers that are configured to form conductive pathways to other external components, such as the IC device 502 and the inductive device 300. For example, the PCB 504 may include one or more metal layers that form circuitry 506 that provides electrical connections between various portions of the IC device 502, the inductive device 300, other external components, or a combination thereof. As described with reference to FIGS. 3A-3C, the inductive device 300 includes the substrate 302 and the integrated inductors 310, 320, 330, and 340 (which each include a corresponding core material disposed within a corresponding cavity, a corresponding set of conductive windings that at least partially encircle the corresponding core material within the corresponding cavity, and a corresponding set of external connectors).

In some examples, the inductive device 300 may include a first set of external connectors disposed on a first surface of the substrate 302 and a second set of external connectors disposed on a second surface of the substrate 302. In some such examples, the first set of external connectors electrically couple the IC device 502 to the integrated inductors 310, 320, 330, and 340, and the IC device 502 is electrically coupled to the PCB 504 at least partially by the second set of external connectors. For example, the sets of external connectors 316, 326, 336, and 346 (e.g., a first set of external connectors) may electrically couple the integrated inductors 310, 320, 330, and 340, respectively, to the IC device 502. To further illustrate, conductive pathways may be provided from the IC device 502 to the PCB 504 by the external connectors 370 and the conductive material within the TSuV 360, the external connectors 372 and the conductive material within the TSuV 362, and the external connectors 374 and the conductive material within the TSuV 364. For example, the external connector 370B may be coupled to a pad 522 of the PCB 504, the external connector 372B may be coupled to a pad 524 of the PCB 504, and the external connector 374B may be coupled to a pad 526 of the PCB 504. Additional conductive pathways between the IC device 502 and the PCB 504 may be provided by additional pads on the IC device 502, additional pads on the PCB 504, and electrical interconnects between the respective pads of the IC device 502 and the PCB 504. For example, a first electrical interconnect 510 coupled to a pad 514 of the IC device 502 and a pad 520 of the PCB 504 may provide a first conductive pathway between the IC device 502 and the PCB 504. As another example, a second electrical interconnect 512 coupled to a pad 516 of the IC device 502 and a pad 528 of the PCB 504 may provide a second conductive pathway between the IC device 502 and the PCB 504. The circuitry 506 may couple one or more of the pads 520-528 to other(s) of the pads 520-528 to provide conductive pathways between various components within the IC device 502, the PCB 504, the inductive device 300, or a combination thereof.

In some examples, the IC device 502 is a PMIC that includes multiple buck regulators that are supported by the integrated inductors 310, 320, 330, and 340. For example, the IC device 502 may include a first buck regulator coupled to the first integrated inductor 310, a second buck regulator coupled to the second integrated inductor 320, a third buck regulator coupled to the third integrated inductor 330, and a fourth buck regulator coupled to the fourth integrated inductor 340. In some such examples, the integrated inductors 310, 320, 330, and 340 may be inductively coupled together such that the IC device 502 (e.g., the PMIC) includes a multi-phase buck regulator. Alternatively, the integrated inductors 310, 320, 330, and 340 may be discrete inductors used as parts of different voltage regulators by the IC device 502.

In a particular implementation, the device 500 includes a first substrate (e.g., the PCB 504), an IC device (e.g., the IC device 502) coupled to the first substrate, and an inductive device (e.g., the inductive device 300) disposed between the first substrate and the IC device. The inductive device includes a second substrate (e.g., the substrate 302) that includes a first integrated inductor (e.g., the first integrated inductor 310). The first integrated inductor includes a first core material (e.g., the first core material 312) disposed within a first cavity of the second substrate and a first set of conductive windings (e.g., the first set of conductive windings 314) that at least partially encircle the first core material within the first cavity.

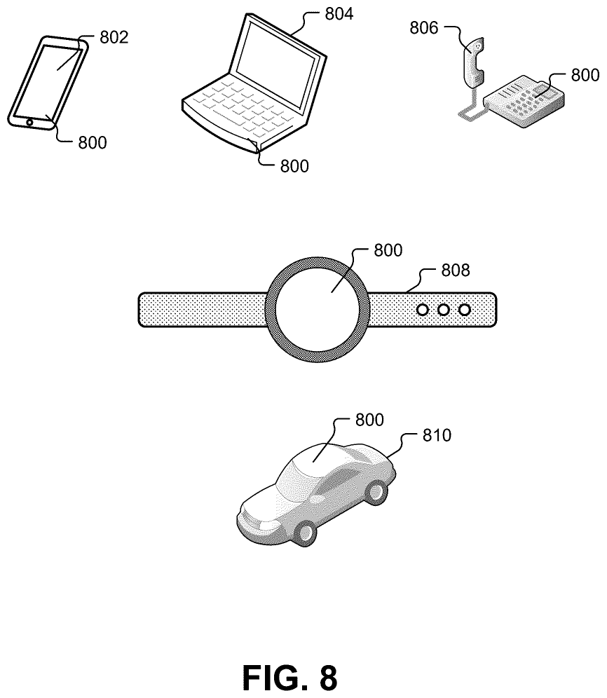

In some implementations, the device 500 can be integrated in a smartphone, a tablet computer, a fixed location terminal device, an automobile, a wearable electronic device, a laptop computer, or some combination thereof, as described in more detail below with reference to FIG. 8. As described with reference to FIG. 5, the device 500 includes the inductive device 300 that includes the integrated inductors 310, 320, 330, and 340 to provide an MPII for the device 500 that satisfies more stringent criteria of advanced PMICs, such as a multi-phase bulk regulator, due to the capability to provide lower signal phase deltas as compared to typical voltage regulators that include SMD inductors coupled to a PCB or a die. A technical advantage of inductive device 300 being included in the device 500 is to support multi-phase buck regulators or other voltage regulator having narrow operating criteria in a cost-effective and compact (e.g., with respect to chip area) solution that has a higher yield than typical SMD inductors.

While FIG. 5 illustrates an example device that includes the inductive device 300, in other examples, one or more additional integrated devices, packages, or some combination thereof can be present in a stacked integrated circuit without departing from the scope of the subject disclosure. Further, the inductive device 300 of FIG. 5 can be integrated with or included within a wide variety of other devices. For example, a device that includes one or more of the inductive device 300 (or any of the inductive device 102, the inductive device 200, and the inductive device 400) disclosed herein can include components such as an application processor, a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. In such devices, the inductive device can be used as a passive component of any of these components (or a combination of these components) that includes active circuitry.

### Exemplary Sequence for Fabricating an Inductive Device Including Integrated Inductor(s)

In some implementations, fabricating an inductive device that includes one or more integrated inductors (e.g., any of the inductive device 102, the inductive device 200, the inductive device 300, or the inductive device 400) includes several processes. FIGS. 6A-6D illustrate an exemplary sequence for fabricating or providing an inductive device that includes one or more integrated inductors, as described with reference to any of FIGS. 1-5. In some implementations, the sequence of FIGS. 6A-6D may be used to provide (e.g., during fabrication of) one or more of the inductive device 102 of FIG. 1, the inductive device 200 of FIGS. 2A-2C, the inductive device 300 of FIGS. 3A-3C, the inductive device 400 of FIG. 4, or the device 500 of FIG. 5.

It should be noted that the sequence of FIGS. 6A-6D may combine one or more stages in order to simplify and/or clarify the sequence for providing or fabricating an inductive device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 6A-6D. Each of the various stages of the sequence illustrated in FIGS. 6A-6D shows an inductive device being formed. In other implementations, a plurality of inductive devices can be formed concurrently.

Stage 1 of FIG. 6A illustrates a state after a substrate 600 is provided. For example, as part of Stage 1, the substrate 600 may be provided from an in-house fabrication process or may be obtained from an external source and be introduced into the sequence for fabricating the inductive device. The substrate 600 may include alumina, glass, HR silicon, or another substance in which TSuVs and blind via cavities may be formed. In some examples, a thickness of the substrate 600 is within a range of 100-200 microns. In some examples, the substrate 600 includes or corresponds to the substrate 104 of FIG. 1, the substrate 202 of FIGS. 2A-2C, the substrate 302 of FIGS. 3A-3C and FIG. 5, or the substrate 402 of FIG. 4.

Stage 2 illustrates a state after a first set of TSuVs 601 are formed within the substrate 600. For example, as part of Stage 2, the first set of TSuVs 601 may be formed within the substrate 600 to enable formation of a portion of conductive windings of an integrated inductor in later Stages of the sequence. In some examples, the first set of TSuVs 601 are formed using laser ablation. In other examples, the first set of TSuVs 601 may be formed using etching or other via formation operations.

Stage 3 illustrates a state after a cavity 602 is formed within the substrate 600. For example, as part of Stage 3, the cavity 602 may be formed in the substrate 600 using laser ablation, etching, cutting, or another technique. Formation of the cavity 602 may be part of a process of forming an integrated inductor, as described in additional detail with reference to a later Stage of the sequence. In some examples, the cavity 602 is a blind substrate cavity (e.g., a cavity that does not penetrate through an entirety of the substrate 600). The width and depth of the cavity 602 may be selected during a design process based on a target inductance or target Q-factor associated with an integrated inductor to be formed in the cavity 602.

Stage 4 of FIG. 6B illustrates a state after a core material 604 is dispensed within the cavity 602. For example, as part of Stage 4, the core material 604 may be dispensed or otherwise deposited within the cavity 602 until the core material 604 substantially fills the cavity 602. In some examples, a planarization or polishing process may be performed after the core material 604 is dispensed within the cavity 602 to form a substantially smooth top surface of the substrate 600 and the core material 604. The core material 604 may include a magnetic filler material or a non-magnetic filler material. As a particular, non-limiting example, the core material 604 may include a magnetic paste. Alternatively, the core material 604 may include ferrite material, magnetic or ferrous powders, iron or iron alloy, other ferromagnetic or ferrimagnetic materials, ceramics or ceramic materials, other magnetic filler material or non-magnetic filler material, or the like. The core material 604 may be selected during a design process based on a target inductance or target Q-factor associated with an integrated inductor to be formed in the cavity 602. In some examples, the core material 604 includes or corresponds to the core material 108 of FIG. 1, any of the core materials 212, 222, 232, or 242 of FIGS. 2A-2C, any of the core materials 312, 322, 332, or 342 of FIGS. 3A-3C and FIG. 5, or any of the core materials 412, 422, 432, or 442 of FIG. 4.

Stage 5 illustrates a state after a dielectric material 606 is deposited on a top surface of the substrate 600 and the core material 604. For example, as part of Stage 5, the dielectric material 606 may be deposited as a dry film on the substrate 600 and the core material 604 to insulate the core material 604. The dielectric material 606 may include a photo-imageable (PI) dielectric material that acts as a PI insulation layer over the core material 604.

Stage 6 illustrates a state after a conductive material is deposited on the dielectric material 606, a bottom surface of the substrate 600, and within the first set of TSuVs 601 to form conductive lines 608. For example, as part of Stage 6, copper plating or another conductive material may be deposited on the dielectric material 606 (e.g., a top surface of the substrate 600) in particular locations (e.g., between adjacent TSuVs of the first set of TSuVs 601) to form the conductive lines 608A. Additionally, the copper plating (or another conductive material) may be deposited within the first set of TSuVs 601 such that the copper plating adheres to the sides of the first set of TSuVs 601 to form the conductive lines 608B. For example, the conductive material deposited within the first set of TSuVs 601 may include a conformal conductive plating, such as a conformal copper plating. The copper plating (or another conductive material) may also be deposited on the bottom surface of the substrate 600 in particular locations (e.g., between adjacent TSuVs of the first set of TSuVs 601) to form the conductive lines 608C. In some examples, the conductive material used to form the conductive lines 608 is double-sided RDL copper plating. The length of the conductive lines 608 and the conductive material used to form the conductive lines 608 may be selected during a design process based on a target inductance or target Q-factor associated with an integrated inductor to be formed from the core material 604 and the conductive lines 608.

Stage 7 of FIG. 6C illustrates a state after attaching the substrate 202 to a temporary carrier layer 614 and depositing a conductive material 610 within the first set of TSuVs 601. For example, as part of Stage 7, the bottom surface of the substrate 600 may be attached to the temporary carrier layer 614 and, after the attachment, the conductive material 610 may be deposited within the first set of TSuVs 601 (e.g., in between the conductive lines 608B along the sides of the first set of TSuVs 601). The conductive material 610 may include copper or another conductive material that is deposited using a dry film fill process. After the conductive material 610 is deposited within the first set of TSuVs 601, the combination of the conductive lines 608 and the conductive material 610 form a set of conductive windings 612 that at least partially encircle the core material 604 within the cavity 602. After the conductive material 610 is deposited within the first set of TSuVs 601, the temporary carrier layer 614 may be unattached from the substrate 600 and removed.

Stage 8 illustrates a state after a bottom dielectric layer 616 is formed on the bottom surface of the substrate 600. For example, as part of Stage 8, the bottom dielectric layer 616 may be formed by depositing a dielectric material on the bottom surface of the substrate 600, over the conductive lines 608C. In some examples, the bottom dielectric layer 616 is formed using a laminate process or a spin-coating process. The bottom dielectric layer 616 may include any type of dielectric material that insulates the conductive lines 608C.

Stage 9 of FIG. 6D illustrates a state after a top dielectric layer 618 is formed on the top surface of the substrate 600. For example, as part of Stage 9, the top dielectric layer 618 may be formed by depositing a dielectric material on the top surface of the substrate 600, over the conductive lines 608A and the dielectric material 606. In some examples, the top dielectric layer 618 is formed using a laminate process or a spin-coating process. The top dielectric layer 618 may include any type of dielectric material that insulates the conductive lines 608A. In some examples, the top dielectric layer 618 and the bottom dielectric layer 616 include the same dielectric material. In some other examples, the top dielectric layer 618 and the bottom dielectric layer 616 include different dielectric materials.

Stage 9 also includes exposing a set of openings 620 in the top dielectric layer 618. For example, as part of Stage 9, the set of openings 620 may be formed in the top dielectric layer 618 to expose portions of the conductive lines 608A (e.g., portions of the conductive windings 612) that are to operate as terminals of an integrated inductor formed from the core material 604 and the conductive windings 612. In some examples, the set of openings 620 may be formed or exposed in the top dielectric layer 618 using a passivation process, such as a violet phosphorus (VP) passivation process.

Stage 10 illustrates a state after a conductive material is deposited within the set of openings 620 to form a set of external connectors 622. For example, as part of Stage 10, a conductive material may be deposited within the set of openings 620 and on the exposed portions of the conductive windings 612 (e.g., the exposed portions of the conductive lines 608A) to form bumps or pillars that act as the set of external connectors 622. In some examples, the set of external connectors 622 include copper pillars (CuPs) (e.g., CuP bumps) or silver-tin alloy (AgSn) solder (e.g., AgSn solder bumps), such that the conductive material used to form the set of external connectors 622 includes copper or AgSn. The set of external connectors 622 may be formed using a flip-chip (FC) bump process, in some examples. The core material 604, the conductive windings 612, and the set of external connectors 622 may form an integrated inductor 624 within the substrate 600. After completion of Stage 10, an inductive device 630 is formed that includes the integrated inductor 624 (e.g., the core material 604, the conductive windings 612, and the set of external connectors 622). Although a single integrated inductor 624 is shown in FIG. 6D, in other examples, operations described with reference to one or more of Stages 1-10 may be repeated in other portions of the substrate 600 to form one or more additional integrated inductors within one or more additional cavities within the substrate 600. In some such examples, the inductive device 630 may be a multi-phase integrated inductor that is configured for use with a multi-phase PMIC buck regulator.

Formation of the inductive device 630 (e.g., an inductive device including one or more integrated inductors) is complete after Stage 10 of FIG. 6D. However, in some implementations, the inductive device 630 can be used to form the device 100 of FIG. 1, the inductive device 200 of FIGS. 2A-2C, the inductive device 300 of FIGS. 3A-3C, the inductive device 400 of FIG. 4, or the device 500 of FIG. 5. For example, the inductive device 630 may be coupled to a die (e.g., the die 120), such as a PMIC, to form the device 100 of FIG. 1. As another example, additionally integrated inductors (e.g., the integrated inductors 220, 230, and 240) in a solenoid configuration may be formed within the substrate 600 to form the inductive device 200 of FIGS. 2A-2C.

As another example, additionally integrated inductors (e.g., the integrated inductors 320, 330, and 340) in a solenoid configuration and external connectors (e.g., the external connectors 370, 372, and 374) may be formed within the substrate 600 to form the inductive device 300 of FIGS. 3A-3C. For example, in addition to the operations described with reference to FIGS. 6A-6D, forming the inductive device 630 may also include forming a second set of TSuVs (e.g., the TSuVs 360-364) within the substrate 600 from the top surface (e.g., a first surface) to the bottom surface (e.g., a second surface that is opposite of the first surface) and depositing a conductive material within the second set of TSuVs, similar to as described with reference to Stages 2, 6, and 7. In this example, forming the inductive device 630 also includes opening a second set of openings in the top dielectric layer 618 above or near the second set of TSuVs and depositing additional conductive material within the second set of openings to form a second set of external connectors (e.g., the external connectors 370, 372, and 374), similar to as described with reference to Stages 9 and 10. In this example, forming the inductive device 630 also includes opening a third set of openings in the bottom dielectric layer 616 below or near the second set of TSuVs and depositing additional conductive material within the third set of openings to form a third set of external connectors that are coupled, through the conductive material within the second set of TSuVs, to the second set of external connectors.

As another example, additionally integrated inductors (e.g., the integrated inductors 420, 430, and 440) in a toroidal configuration may be formed within the substrate 600 to form the inductive device 400 of FIG. 4. As another example, the inductive device 630 may be coupled to an IC device (e.g., the IC device 502), such as a PMIC, and to another substrate (e.g., the PCB 504) to form the device 500 of FIG. 5.

Although certain Stages are illustrated in FIGS. 6A-6D in forming the inductive device 630, other processes can be included in the fabrication of the inductive device 630 without departing from the scope of the subject disclosure. For example, fabricating the inductive device 630 can include formation of additional TSuVs, deposition of conductive material within the additional TSuVs, and deposition of conductive material above or near openings of the TSuVs to form additional external connectors that are configured to provide conductive pathways from the top surface of the inductive device 630 to the bottom surface of the inductive device 630.

### Exemplary Flow Diagram of a Method for Fabricating an Inductive Device Including Integrated Inductor(s)

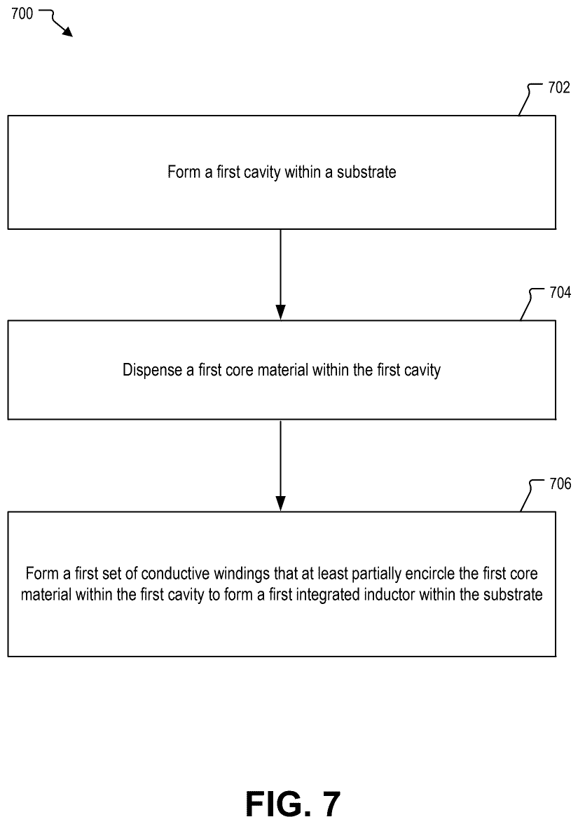

In some implementations, fabricating a device including an inductive device that includes one or more integrated inductors includes several processes. FIG. 7 illustrates an exemplary flow diagram of a method 700 of fabricating an illustrative device that includes an inductive device that includes one or more integrated inductors. In a particular aspect, one or more operations of the method 700 are performed by one or more processors of a fabrication system. In some implementations, operations of the method 700 may be stored as instructions by a non-transitory computer-readable storage medium, and the instructions may be executable by at least one processor to cause the at least one processor to perform operations of the method 700. In some implementations, the method 700 of FIG. 7 may be used to provide or fabricate any of the device 100 of FIG. 1, the inductive device 200 of FIGS. 2A-2C, the inductive device 300 of FIGS. 3A-3C, the inductive device 400 of FIG. 4, the device 500 of FIG. 5, or the inductive device 630 of FIG. 6.

It should be noted that the method 700 of FIG. 7 may combine one or more processes in order to simplify and/or clarify the method for providing or fabricating an integrated circuit device. In some implementations, the order of the processes may be changed or modified.

The method 700 forms a first integrated inductor within a substrate and includes forming a first cavity within the substrate, at block 702. For example, Stage 3 of FIG. 6A illustrates and describes examples of forming the cavity 602 within the substrate 600. The first cavity of the method 700 may include or correspond to the cavity 602 of FIGS. 6A-6D, and the substrate of the method 700 may include the substrate 104 of FIG. 1, the substrate 202 of FIGS. 2A-2C, the substrate 302 of FIGS. 3A-3C and FIG. 5, the substrate 402 of FIG. 4, or the substrate 600 of FIGS. 6A-6D.

The method 700 includes dispensing a first core material within the first cavity, at block 704. For example, Stage 4 of FIG. 6B illustrates and describes examples of dispensing the core material 604 within the cavity 602. The first core material of the method 700 can include the core material 108 of FIG. 1, the first core material 212 of FIGS. 2A-2B, the first core material 312 of FIGS. 3A-3B, the first core material 412 of FIG. 4, or the core material 604 of FIGS. 6B-6D.

The method 700 includes forming a first set of conductive windings that at least partially encircle the first core material within the first cavity, at block 706, to form the first integrated inductor. For example, Stages 6 and 7 of FIGS. 6B and 6C illustrate and describe examples of forming the set of conductive windings 612 that includes the conductive lines 608 and the conductive material 610. The first set of conductive windings of the method 700 can include the conductive windings 110 of FIG. 1, the first set of conductive windings 214 of FIGS. 2A-2C, the first set of conductive windings 314 of FIGS. 3A-3C and FIG. 5, the first set of conductive windings 414 of FIG. 4, or the set of conductive windings 612 of FIGS. 6C-6D. The first integrated inductor formed by the method 700 may include or correspond to the integrated inductor 106 of FIG. 1, the first integrated inductor 210 of FIGS. 2A-2C, the first integrated inductor 310 of FIGS. 3A-3C and FIG. 5, the first integrated inductor 410 of FIG. 4, or the integrated inductor 624 of FIG. 6D.

In some implementations, forming the first set of conductive windings includes forming a first set of TSuVs within the substrate. For example, Stage 2 of FIG. 6A illustrates and describes examples of forming the first set of TSuVs 601 within the substrate 600. The first set of TSuVs of the method 700 can include the first set of TSuVs 218 of FIGS. 2A-2C, the first set of TSuVs 318 of FIGS. 3A-3C and FIG. 5, or the first set of TSuVs 601 of FIGS. 6A-6D. Forming the first set of conductive windings may also include depositing a conductive material on a first surface of the substrate and within the first set of through-substrate vias. For example, Stage 6 of FIG. 6B illustrates and describes depositing a conductive material on the top surface of the substrate 600 to form the conductive lines 608A, and Stage 7 of FIG. 6C illustrates and describes examples of depositing the conductive material 610 within the first set of TSuVs 601 (e.g., on the conductive lines 608B). The conductive material of the method 700 can include a conductive material associated with the conductive windings 110 of FIG. 1, a conductive material associated with the first set of conductive windings 214 of FIGS. 2A-2C, a conductive material associated with the first set of conductive windings 314 of FIGS. 3A-3C and FIG. 5, a conductive material associated with the first set of conductive windings 414 of FIG. 4, a conductive material associated with the conductive lines 608A of FIGS. 6B-6D, or the conductive material 610 of FIGS. 6C-6D. Forming the first set of conductive windings may also include depositing the conductive material on a second surface of the substrate that is opposite of the first surface. For example, Stage 6 of FIG. 6B illustrates and describes depositing a conductive material on the bottom surface of the substrate 600 to form the conductive lines 608C.

In some implementations, the method 700 includes forming a second integrated inductor within the substrate. Forming the second integrated inductor includes forming a second cavity within the substrate. The second integrated inductor of the method 700 can include the second integrated inductor 220 of FIGS. 2A-2C, the second integrated inductor 320 of FIGS. 3A-3C and FIG. 5, or the second integrated inductor 420 of FIG. 4. Forming the second integrated inductor also includes dispensing a second core material within the second cavity and forming a second set of conductive windings that at least partially encircle the second core material within the second cavity. The second core material of the method 700 can include the second core material 222 of FIGS. 2A-2C, the second core material 322 of FIGS. 3A-3C and FIG. 5, or the second core material 422 of FIG. 4, and the second set of conductive windings of the method 700 can include the second set of conductive windings 224 of FIGS. 2A-2C, the second set of conductive windings 324 of FIGS. 3A-3C and FIG. 5, or the second set of conductive windings 424 of FIG. 4. In some such implementation, the first core material includes a first magnetic filler material and the second core material includes a second magnetic filler material that is different than the first magnetic filler material. Alternatively, the first core material and the second core material may include the same magnetic filler material or the same non-magnetic filler material. Alternatively, one of the first core material and the second core material may include a magnetic filler material, and the other of the first core material and the second core material may include a non-magnetic filler material.

In some implementations, the method 700 includes exposing a first set of openings within a first surface of the substrate and over a first portion of the first set of conductive windings and depositing a conductive material within the first set of openings to form a first set of external connectors coupled to the first integrated inductor. For example, Stage 9 of FIG. 6D illustrates and describes examples of exposing the set of openings 620 within the top dielectric layer 618 of the substrate 600, and Stage 10 of FIG. 6D illustrates and describes examples of depositing a conductive material within the set of openings 620 to form the set of external connectors 622 coupled to the integrated inductor 624. The first set of external connectors of the method 700 can include the external connectors 112 of FIG. 1, the first external connectors 216 of FIGS. 2A-2C, the first set of external connectors 316 of FIGS. 3A-3C and FIG. 5, the first set of external connectors 416 of FIG. 4, or the set of external connectors 622 of FIG. 6D. In some such implementations, the method 700 further includes forming a set of TSuVs within the substrate from the first surface to a second surface that is opposite of the first surface, depositing the conductive material within the set of TSuVs, opening a second set of openings in the first surface of the substrate above the set of TSuVs, depositing additional conductive material within the second set of openings to form a second set of external connectors, opening a third set of openings in the second surface of the substrate below the set of TSuVs, and depositing additional conductive material within the third set of openings to form a third set of external connectors coupled to the second set of external connectors. For example, the second set of external connectors and the third set of external connectors of the method 700 can include the external connectors 370-374 of FIGS. 3A-3C and FIG. 5, and the set of TSuVs of the method 700 may include or correspond to the TSuVs 360-364 of FIGS. 3A-3C and FIG. 5.

### Exemplary Electronic Devices

FIG. 8 illustrates various electronic devices that may include or be integrated with any of the device 100 (that includes the inductive device 102), the inductive device 200, the inductive device 300, the inductive device 400, the device 500 (that includes the inductive device 300), or the inductive device 630. For example, a mobile phone device 802, a laptop computer device 804, a fixed location terminal device 806, a wearable device 808, or a vehicle 810 (e.g., an automobile or an aerial device) may include a device 800. The device 800 can include, for example, any of the device 100 or the device 500, and/or any other integrated device that includes the inductive devices 200, 300, 400, or 630 described herein. The devices 802, 804, 806 and 808 and the vehicle 810 illustrated in FIG. 8 are merely exemplary. Other electronic devices may also feature the device 800 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1-8 may be rearranged and/or combined into a single component, process, feature or function or embodied in several components, processes, or functions. Additional elements, components, processes, and/or functions may also be added without departing from the disclosure. It should also be noted FIGS. 1-8 and its corresponding description in the present disclosure is not limited to dies and/or ICs. In some implementations, FIG. 1-8 and its corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first,” “second,” “third,” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate,” “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical pathway for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.
According to Example 1, an apparatus includes a substrate that includes a first integrated inductor; wherein the first integrated inductor includes: a first core material disposed within a first cavity of the substrate; and a first set of conductive windings that at least partially encircle the first core material within the first cavity.
Example 2 includes the apparatus of Example 1, wherein the first core material includes a magnetic filler material.
Example 3 includes the apparatus of Example 1 or Example 2, wherein the first core material includes a non-magnetic filler material.
Example 4 includes the apparatus of any of Examples 1 to 3, wherein the first set of conductive windings includes: a first set of conductive lines on a first surface of the substrate; a second set of conductive lines on a second surface of the substrate that is opposite of the first surface; and conductive material within a first set of through-substrate vias that extend between the first surface and the second surface.
Example 5 includes the apparatus of any of Examples 1 to 4, wherein the substrate includes a plurality of integrated inductors, the plurality of integrated inductors including at least the first integrated inductor and a second integrated inductor, and wherein the second integrated inductor includes: a second core material disposed within a second cavity of the substrate; and a second set of conductive windings that at least partially encircle the second core material within the second cavity.
Example 6 includes the apparatus of Example 5, wherein the first core material is a different material than the second core material.
Example 7 includes the apparatus of Example 5, wherein the first core material and the second core material are the same material.
Example 8 includes the apparatus of any of Examples 5 to 7, wherein each respective cavity and each respective set of conductive windings of the plurality of integrated inductors extend along a common axis in a particular direction within the substrate to form a multi-phase solenoid inductor.
Example 9 includes the apparatus of any of Examples 5 to 7, wherein each respective cavity and each respective set of conductive windings of the plurality of integrated inductors extend along a loop within the substrate to form a multi-phase toroidal inductor.
Example 10 includes the apparatus of any of Examples 1 to 9, and further includes a first set of external connectors disposed on a first surface of the substrate and coupled to the first integrated inductor, the first set of external connectors configured to be coupled to a first external device.
Example 11 includes the apparatus of Example 10, and further includes: a second set of external connectors disposed on the first surface of the substrate, the second set of external connectors configured to be coupled to the first external device; a third set of external connectors disposed on a second surface of the substrate that is opposite of the first surface, the third set of external connectors configured to be coupled to a second external device; and a set of through-substrate vias between respective external connectors of the second set of external connectors and respective external connectors of the third set of external connectors.
According to Example 12 a method includes forming a first integrated inductor within a substrate, wherein forming the first integrated inductor includes: forming a first cavity within the substrate; dispensing a first core material within the first cavity; and forming a first set of conductive windings that at least partially encircle the first core material within the first cavity.
Example 13 includes the method of Example 12, wherein forming the first set of conductive windings includes: forming a first set of through-substrate vias within the substrate; depositing a conductive material on a first surface of the substrate and within the first set of through-substrate vias; and depositing the conductive material on a second surface of the substrate that is opposite of the first surface.
Example 14 includes the method of Example 12 or Example 13, and further includes forming a second integrated inductor within the substrate, wherein forming the second integrated inductor includes: forming a second cavity within the substrate; dispensing a second core material within the second cavity; and forming a second set of conductive windings that at least partially encircle the second core material within the second cavity.
Example 15 includes the method of Example 14, wherein the first core material includes a first magnetic filler material, and wherein the second core material includes a second magnetic filler material that is different than the first magnetic filler material.
Example 16 includes the method of any of Examples 12 to 15, and further includes: exposing a first set of openings within a first surface of the substrate and over a first portion of the first set of conductive windings; and depositing a conductive material within the first set of openings to form a first set of external connectors coupled to the first integrated inductor.
Example 17 includes the method of Example 16, and further includes: forming a set of through-substrate vias within the substrate from the first surface to a second surface that is opposite of the first surface; depositing the conductive material within the set of through-substrate vias; opening a second set of openings in the first surface of the substrate above the set of through-substrate vias; depositing additional conductive material within the second set of openings to form a second set of external connectors; opening a third set of openings in the second surface of the substrate below the set of through-substrate vias; and depositing additional conductive material within the third set of openings to form a third set of external connectors coupled to the second set of external connectors.
According to Example 18, an apparatus includes: a first substrate; an integrated circuit (IC) device coupled to the first substrate; and an inductive device disposed between the first substrate and the IC device, wherein the inductive device includes: a second substrate that includes a first integrated inductor; and wherein the first integrated inductor includes: a first core material disposed within a first cavity of the second substrate; and a first set of conductive windings that at least partially encircle the first core material within the first cavity.
Example 19 includes the apparatus of Example 18, wherein the inductive device further includes: a first set of external connectors disposed on a first surface of the second substrate, wherein the first set of external connectors electrically couple the IC device to the first integrated inductor; and a second set of external connectors disposed on a second surface of the second substrate that is opposite of the first surface, wherein the IC device is electrically coupled to the first substrate at least partially by the second set of external connectors.
Example 20 includes the apparatus of Example 18 or Example 19, wherein the IC device is a power management integrated circuit (PMIC) that includes a first buck regulator coupled to the first integrated inductor.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. An apparatus comprising:
a substrate that includes a first integrated inductor;
wherein the first integrated inductor includes:
a first core material disposed within a first cavity of the substrate; and
a first set of conductive windings that at least partially encircle the first core material within the first cavity.

2. The apparatus of claim 1, wherein the first core material includes a magnetic filler material.

3. The apparatus of claim 1, wherein the first core material includes a non-magnetic filler material.

4. The apparatus of claim 1, wherein the first set of conductive windings includes:
a first set of conductive lines on a first surface of the substrate;
a second set of conductive lines on a second surface of the substrate that is opposite of the first surface; and
conductive material within a first set of through-substrate vias that extend between the first surface and the second surface.

5. The apparatus of claim 1, wherein the substrate includes a plurality of integrated inductors, the plurality of integrated inductors including at least the first integrated inductor and a second integrated inductor, and wherein the second integrated inductor includes:
a second core material disposed within a second cavity of the substrate; and
a second set of conductive windings that at least partially encircle the second core material within the second cavity.

6. The apparatus of claim 5, wherein the first core material is a different material than the second core material.

7. The apparatus of claim 5, wherein the first core material and the second core material are the same material.

8. The apparatus of claim 5, wherein each respective cavity and each respective set of conductive windings of the plurality of integrated inductors extend along a common axis in a particular direction within the substrate to form a multi-phase solenoid inductor.

9. The apparatus of claim 5, wherein each respective cavity and each respective set of conductive windings of the plurality of integrated inductors extend along a loop within the substrate to form a multi-phase toroidal inductor.

10. The apparatus of claim 1, further comprising:
a first set of external connectors disposed on a first surface of the substrate and coupled to the first integrated inductor, the first set of external connectors configured to be coupled to a first external device.

11. The apparatus of claim 10, further comprising:
a second set of external connectors disposed on the first surface of the substrate, the second set of external connectors configured to be coupled to the first external device;
a third set of external connectors disposed on a second surface of the substrate that is opposite of the first surface, the third set of external connectors configured to be coupled to a second external device; and
a set of through-substrate vias between respective external connectors of the second set of external connectors and respective external connectors of the third set of external connectors.

12. A method comprising:
forming a first integrated inductor within a substrate, wherein forming the first integrated inductor includes:
forming a first cavity within the substrate;
dispensing a first core material within the first cavity; and
forming a first set of conductive windings that at least partially encircle the first core material within the first cavity.

13. The method of claim 12, wherein forming the first set of conductive windings includes:
forming a first set of through-substrate vias within the substrate;
depositing a conductive material on a first surface of the substrate and within the first set of through-substrate vias; and
depositing the conductive material on a second surface of the substrate that is opposite of the first surface.

14. The method of claim 12, further comprising:
forming a second integrated inductor within the substrate, wherein forming the second integrated inductor includes:
forming a second cavity within the substrate;
dispensing a second core material within the second cavity; and
forming a second set of conductive windings that at least partially encircle the second core material within the second cavity.

15. The method of claim 14, wherein the first core material includes a first magnetic filler material, and wherein the second core material includes a second magnetic filler material that is different than the first magnetic filler material.

16. The method of claim 12, further comprising:
exposing a first set of openings within a first surface of the substrate and over a first portion of the first set of conductive windings; and
depositing a conductive material within the first set of openings to form a first set of external connectors coupled to the first integrated inductor.

17. The method of claim 16, further comprising:
forming a set of through-substrate vias within the substrate from the first surface to a second surface that is opposite of the first surface;
depositing the conductive material within the set of through-substrate vias;
opening a second set of openings in the first surface of the substrate above the set of through-substrate vias;
depositing additional conductive material within the second set of openings to form a second set of external connectors;
opening a third set of openings in the second surface of the substrate below the set of through-substrate vias; and
depositing additional conductive material within the third set of openings to form a third set of external connectors coupled to the second set of external connectors.

18. An apparatus comprising:
a first substrate;
an integrated circuit (IC) device coupled to the first substrate; and
an inductive device disposed between the first substrate and the IC device, wherein the inductive device includes:
a second substrate that includes a first integrated inductor; and
wherein the first integrated inductor includes:
a first core material disposed within a first cavity of the second substrate; and
a first set of conductive windings that at least partially encircle the first core material within the first cavity.

19. The apparatus of claim 18, wherein the inductive device further includes:
a first set of external connectors disposed on a first surface of the second substrate, wherein the first set of external connectors electrically couple the IC device to the first integrated inductor; and
a second set of external connectors disposed on a second surface of the second substrate that is opposite of the first surface, wherein the IC device is electrically coupled to the first substrate at least partially by the second set of external connectors.

20. The apparatus of claim 18, wherein the IC device is a power management integrated circuit (PMIC) that includes a first buck regulator coupled to the first integrated inductor.
